(19) United States
(12) Patent Application Publication
(10) Pub. No.: US 2020/0244056 A1
(43) Pub. Date: Jul. 30, 2020

(54) ELECTRICAL DEVICE ENCLOSURE

(71) Applicant: NSi Industries, LLC, Huntersville, NC (US)

(72) Inventor: Allen John Ustianowski, Huntersville, NC (US)

(21) Appl. No.: 16/257,465

(22) Filed: Jan. 25, 2019

(51) Int. Cl. H02G 3/14; H02G 3/08; H02B 1/38; H05K 5/02; H05K 7/14

(52) U.S. Cl. CPC H02G 3/14; H02G 3/086; H02G 3/085; E05D 7/1005; H05K 5/0226; H05K 7/1417; H02G 3/088; H02B 1/38

(57) ABSTRACT

An electrical device enclosure that includes a base having a base wall for being mounted to a supporting structure with at least one access opening in the base wall for receiving an insert plate having electrical device opening for receiving an electrical device to extend therethrough. A plurality of raised bosses are positioned on a rear side of the base wall proximate the access opening. The insert plates have a plurality of attachment elements for cooperating with respective ones of the bosses for mounting the insert plate to the rear side of the base wall and against the supporting structure. A raised cover is pivotally-mounted on the base and movable for selectively enclosing and exposing the base.

### TECHNICAL FIELD AND BACKGROUND OF INVENTION

This invention relates to electrical device enclosures of the general type that are installed out of doors to protect electrical devices such as electrical switches, power outlets and the like from water, such as may be directed onto the electrical devices by irrigation sprinklers, rain, etc. Such enclosures are known in the art, and are generally described as “waterproof” enclosures because they provide a means of sheltering the switches, outlets, etc. from contact with water while the electrical devices are in use. This type of enclosure is distinct from outside outlets that have a spring-loaded cover that protects the outlet, for example, when not in use, but not while an electrical device such as the plug of a power cord is plugged into the outlet. This type of enclosure is most often designed to accommodate either a single electrical device (“single gang”), or a pair of electrical devices (“double gang”).

Existing single and double gang enclosures typically have an access opening on a base that is designed to accommodate an insert plate with an electrical device opening that matches the outline shape of an electrical device, for example a flip-type light switch, standard two or three blade 110V or 220V outlet, among others. These outline shapes vary considerably to take into account the varying outline shapes of many different types of electrical devices, and some include a series of “knock-out” perforations by which a single insert plate can be customized for use with several differently shaped and/or sized electrical devices. Prior art enclosures typically have insert plates that are specific to the size of the enclosure, i.e., an insert plate for a single gang enclosure will not fit into the access opening of a double gang enclosure, and vice versa.

Another drawback of prior art enclosures is the manner in which the insert plates are mounted into the access openings. Typically, the insert plate is mounted into the access opening in the base from the front, meaning that unless it is very securely mounted, it can come loose when, for example, a plug is being pulled from an outlet.

### SUMMARY OF THE INVENTION

It is therefore an object of the present invention to provide electrical device enclosures of different capacities that will accommodate in access openings the same insert plates.

It is another object of the invention to provide electrical device enclosures that permit insert plates to be quickly and easily mounted to the base of the enclosure from the rear so that the insert plate is sandwiched securely between the back wall of the enclosure and the supporting structure to which the enclosure is mounted.

These and other objects and advantages of the invention are achieved by providing an electrical device enclosure that includes a base having a base wall for being mounted to a supporting structure with at least one access opening in the base wall for receiving an insert plate having electrical device opening for receiving an electrical device to extend therethrough. A plurality of raised bosses are positioned on a rear side of the base wall proximate the access opening. The insert plates have a plurality of attachment elements for cooperating with respective ones of the bosses for mounting the insert plate to the rear side of the base wall and against the supporting structure. A raised cover is pivotally-mounted on the base wall and movable for selectively enclosing and exposing the base wall.

According to another aspect of the invention, a plurality of insert plates are provided, each insert plate having at least one opening of a predetermined selected shape and size for receiving an electrical device of a predetermined selected shape and size to extend therethrough.

According to another aspect of the invention, the enclosure includes at least one knockout panel formed on a wall edge of the base for being removed to receive an electrical cord therethrough. At least one base hinge member is mounted on the base and at least one complementary cover hinge member is mounted on the cover for cooperating with the base hinge member to receive a hinge pin.

According to another aspect of the invention, the access opening is sized to receive at least any two of the plurality of insert plates in a side-by-side relation.

According to another aspect of the invention, a laterally outwardly-extending base tab is formed on the base and a complimentary laterally outwardly-extending cover tab is formed on the cover and positioned over the base tab when the cover is closed against the base, both the base tab and the cover tab having an opening therein in registration with each other to receive a lock.

According to another aspect of the invention, the base and the cover are rectangular and adapted to be positioned on the supporting structure with either a long side or a short side of the base and cover extending laterally in a side-to-side orientation.

According to another aspect of the invention, a first base hinge is mounted on the long side of the base and a second base hinge is mounted on the short side of the base. A first cover hinge is mounted on the long side of the cover and a second cover hinge is mounted on the short side of the cover and cooperates with a respective one of the first and second base hinge member to receive a hinge pin. The enclosure may be mounted on the supporting structure in an orientation permitting either the long side of the base or the short side of the base to be positioned laterally with respect to the supporting structure.

According to another aspect of the invention, an electrical device enclosure is provided that includes an equilateral base having a base wall for being mounted to a supporting structure and at least one access opening in the base wall for receiving at least two insert plates each having an electrical device opening for receiving an electrical device to extend therethrough. A plurality of raised bosses are positioned on a rear side of the base wall proximate the access opening, and each of the at least two insert plates having thereon a plurality of attachment elements for cooperating with respective ones of the bosses for mounting the insert plate to the rear side of the base wall and against the supporting structure.

According to another aspect of the invention, the raised bosses are semispherical and the attachment elements comprise outwardly extending tabs having a semicircular opening sized to fit snugly around the raised semispherical bosses.

According to another aspect of the invention, a plurality of insert plates are provided, each insert plate having at least one opening of a predetermined selected shape and size for receiving an electrical device of a predetermined selected shape and size to extend therethrough.

According to another aspect of the invention, at least one knockout panel is formed on a wall edge of the base for being removed to receive an electrical cord therethrough.

According to another aspect of the invention, at least one base hinge member is mounted on the base and at least one complementary cover hinge member is mounted on the cover for cooperating with the base hinge member to receive a hinge pin.

According to another aspect of the invention, an electrical device enclosure kit is provided, and includes a first electrical device enclosure with a rectangular base having a base wall for being mounted to a supporting structure and adapted to be positioned on the supporting structure with either a long side or a short side of the base extending laterally in a side-to-side orientation. At least one access opening in the base wall is provided for receiving an insert plate having electrical device opening for receiving an electrical device to extend therethrough. A plurality of raised bosses are positioned on a rear side of the base wall proximate the access opening. The insert plate has thereon a plurality of attachment elements for cooperating with respective ones of the bosses for mounting the insert plate to the rear side of the base wall and against the supporting structure. A raised cover is pivotally-mounted on the base and movable for selectively enclosing and exposing the base. A second electrical device enclosure is provided and includes an equilateral base having a base wall for being mounted to a supporting structure and at least one access opening in the base wall for receiving at least two insert plates, each having an electrical device opening for receiving an electrical device to extend therethrough. A plurality of raised bosses are positioned on a rear side of the base wall proximate the access opening, and each of the at least two insert plates have thereon a plurality of attachment elements for cooperating with respective ones of the bosses for mounting the insert plate to the rear side of the wall and against the supporting structure. Each of the insert plates for both the rectangular and equilateral enclosure are sized to fit into the access opening of the rectangular base wall of the equilateral base to be held in position by the raised bosses and attachment elements.

According to another aspect of the invention, at least one knockout panel is formed on a wall edge of the base of both the rectangular and equilateral bases for being removed to receive an electrical cord therethrough. At least one base hinge member is mounted on a wall edge of both the rectangular and equilateral bases and at least one cover hinge is mounted on a wall edge of both the rectangular and equilateral cover and cooperates with the base hinge members of respective rectangular and equilateral covers to receive a hinge pin.

According to another aspect of the invention, the access opening of the equilateral base is sized to receive at least any two of the plurality of insert plates in a side-by-side relation.

According to another aspect of the invention, a laterally outwardly-extending base locking tab is formed on each base and a complimentary laterally outwardly-extending cover locking tab is formed on each cover and is positioned over the base locking tab when the cover is closed against the base, both the base locking tab and the cover locking tab having an opening therein in alignment with each other to receive a lock.

### BRIEF DESCRIPTION OF THE DRAWINGS

The invention is best understood when the following detailed description of the invention is read with reference to the accompanying drawings, in which:

FIG. 1 is an exploded perspective view of a single gang electrical device enclosure, including a selected two insert plates;

FIG. 2 is an elevation of the single gang electrical device enclosure of FIG. 1;

FIG. 3 is a elevation view showing attachment of a selected insert plate into a single gang enclosure, viewed from a rear side of the base;

FIG. 4 is an exploded perspective view of a double gang electrical device enclosure, including a selected two single gang insert plates and one double gang insert plate;

FIG. 5 is a rear elevation of the base of the double gang electrical device enclosure showing insertion of a double gang insert plate into the access opening;

FIG. 6 is a rear elevation of the base of the double gang electrical device enclosure showing insertion of a pair of single gang insert plates into the access opening; and

FIG. 7 is a perspective view of the double gang electrical device enclosure showing the rear of the base and the top of the cover.

### DETAILED DESCRIPTION OF THE PREFERRED EMBODIMENT

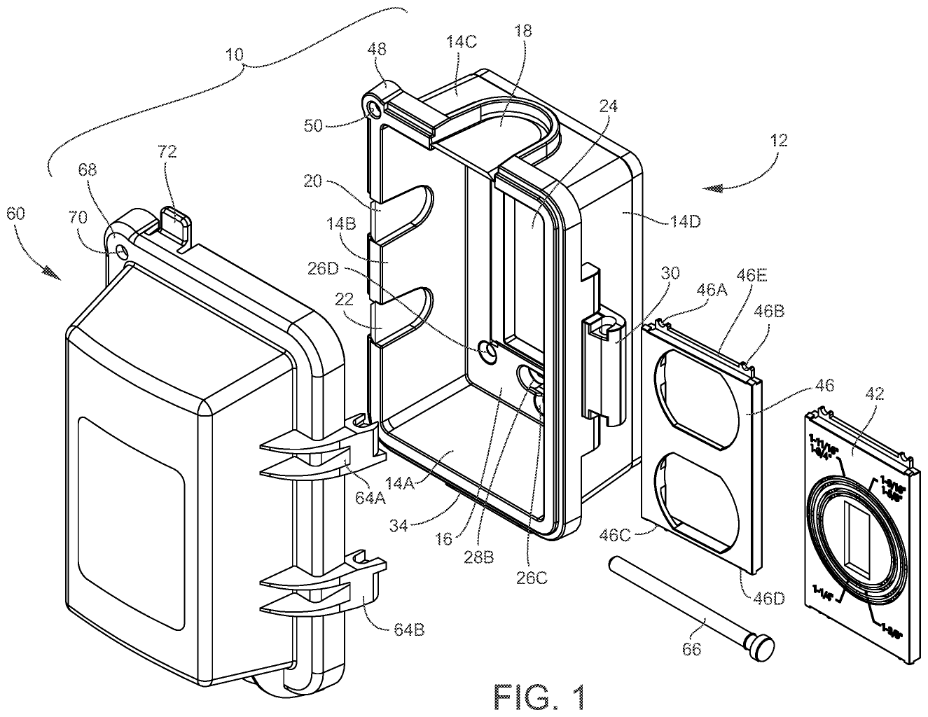

Referring now to FIGS. 1, 2 and 3 of the drawings, a single gang electrical device enclosure 10 according to one preferred embodiment of the invention is shown, and includes a base 12, including base side walls 14A-D, and a rear base wall 16. The enclosure 10 is shown inverted with the bottom side wall 14C at the top of the drawing to show the knockout panel 18 in the bottom side wall 14C. The side wall 14B includes a pair of knockout panels 20 and 22 that will typically be used when the side wall 14B is in an orientation to serve as the “bottom” of the enclosure 10.

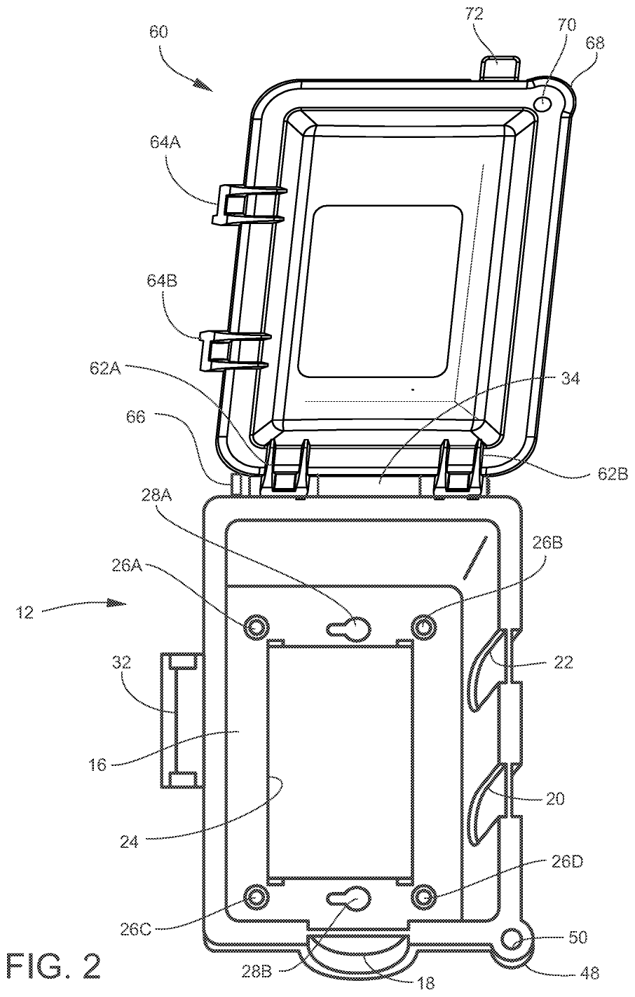

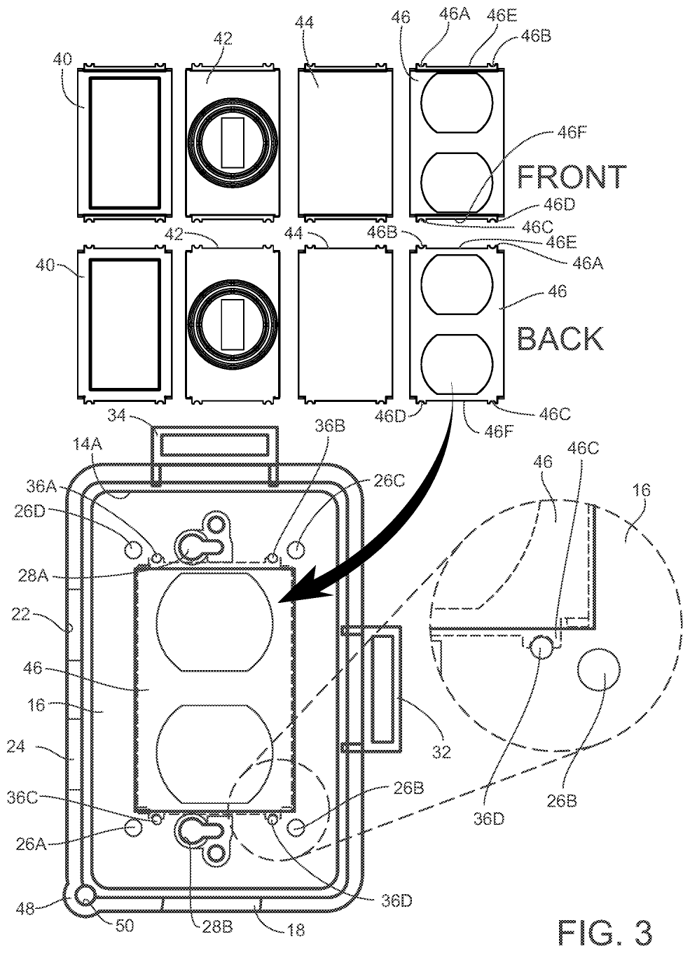

As best shown in FIGS. 2 and 3, the rear wall 16 includes a centrally-positioned access opening 24, standoffs 26A-D mounting screw keyholes 28A-B and mounting screw holes 30A-B. The mounting screw keyholes 28A-B stand proud of the rear surface of the base 12. Side wall 14D includes a base hinge element 32 and side wall 14A includes a base hinge element 34. Bosses 36A-D in the form of semispherical raised elements extend outwardly from the back surface of the rear wall 16 the same distance as the screw keyholes 28A-B. Insert plates 40, 42, 44 and 46 are exemplary of insert plates having access openings of various sizes and shapes or, in the case of insert plate 44, no access opening.

By way of example, insert plate 46 includes outwardly projecting tabs 46A-D that include semicircular openings that fit around the bosses 36A-D, respectively, to lock the insert plate 46 into place in the access opening 24. Support shoulders 46E and 46F extend between the tabs 46A, 46B and 46C, 46D to support the insert plate 46 in the access opening 24. The thickness of the insert plate 46 is such that it is flush with the level of the standoffs 26A-D on the back side of the rear wall 16 and also flush with the front side of the rear wall 16 within the enclosure 10. The insert plate 46 is therefore held against movement when the base is installed on a support structure by the tabs 46A-D and the support shoulders 46E-F. Because the insert plate 46 is mounted on the back side of the rear wall 16, it is held in its installed position by the support structure to which the base 12 is mounted. While not discussed specifically, the other insert plates 40, 42 and 44 have identical tabs that include semicircular openings that fit around the bosses 36A-D, respectively, and support shoulders to lock the insert plate 46 into place in the access opening 24. The base 12 also includes a base locking tab 48 positioned on a corner of the base 12 remote from the base hinge element 30 with a hole 50 formed therein.

Referring to FIG. 2, a cover 60 is preferably fabricated of a transparent or semitransparent plastic and includes cover hinge elements 62A-B and 64A-B, each spaced-apart to receive respective base hinge elements 30 and 32. The cover 60 is deep enough to fully close against the base 12. If the enclosure 10 is intended to be mounted with the knockout panel 18 at the bottom with the cover 60 opening from the top, cover hinge elements 62A-B are placed on either side of the base hinge element 34, and a hinge pin 66, see FIG. 1, is inserted in aligned openings, not shown, in the cover hinge elements 62A-B and 34. The same arrangement can be used with the enclosure 10 mounted laterally with the knockout panels 20, 22 at the bottom, in which case the cover 60 will open to one side.

If the enclosure 10 is intended to be mounted with the knockout panels 20, 22 at the bottom with the cover 60 opening from the top, cover hinge elements 64A-B are placed on either side of base hinge element 32 and the hinge pin 66 is inserted in aligned openings, not shown, in the cover hinge elements 64A-B and 32. The same arrangement can be used with the enclosure 10 mounted vertically with the knockout panels 20, 22 at the side, in which case the cover 60 will open from one side.

The cover 60 includes a cover locking tab 68 formed on a corner of the cover 60 remote from cover hinge elements 62A-B. A hole 70 in the cover locking tab 68 aligns with the hole 50 in the base locking tab 48 when the cover 60 is closed and the cover can be locked with a small padlock, zip-tie or some other means. A cover lift tab 72 formed on the corner of the cover 60 adjacent to the cover locking tab 68 provides a means of easily opening the cover 60 away from the base 12.

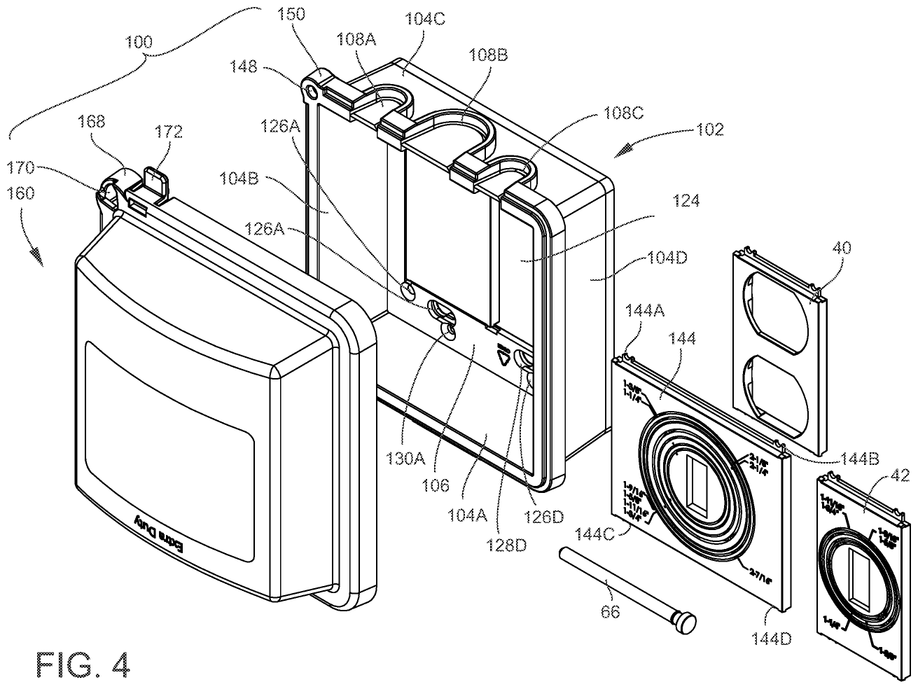

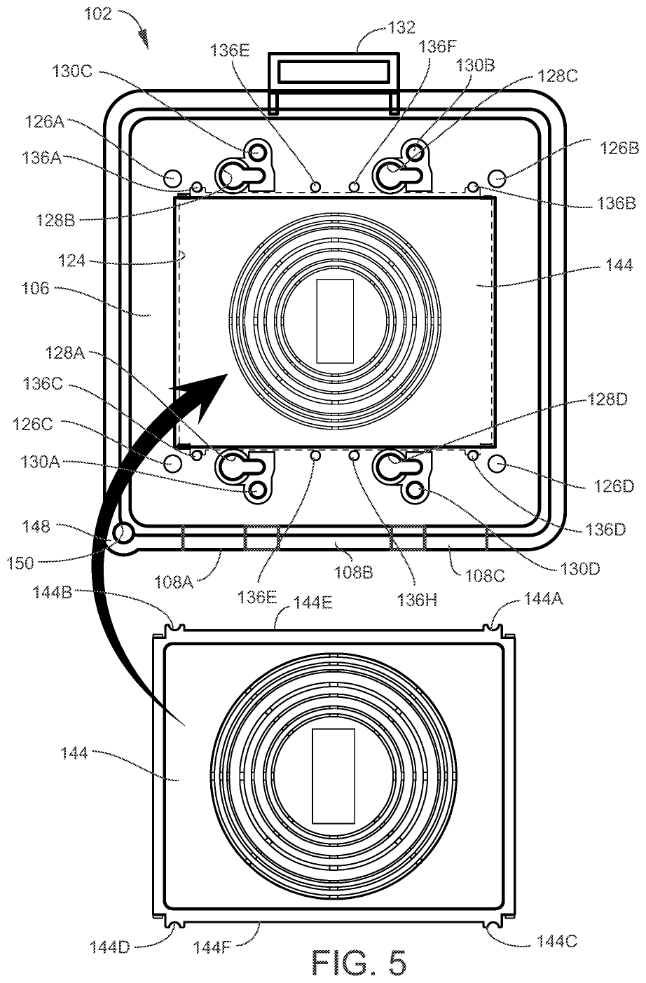

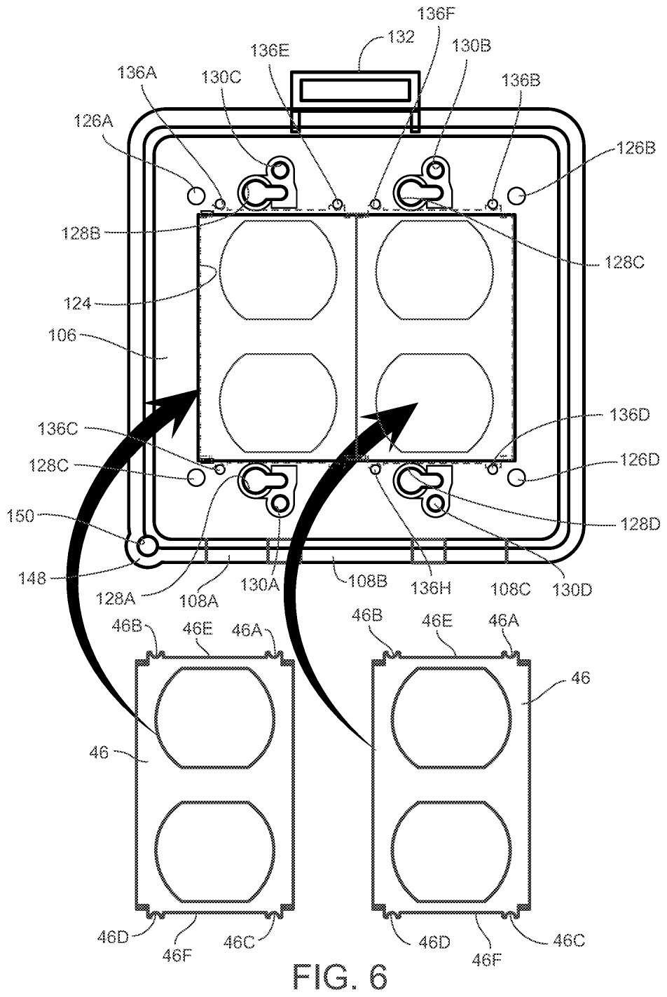

Referring to FIGS. 4-7, a double gang electrical device enclosure 100 according to one preferred embodiment of the invention is shown, and includes a base 102, including side walls 104A-D, and a rear wall 106. The enclosure 100 is shown inverted with the bottom side wall at the top of the drawing to show the knockout panels 108A-C in side wall 104C. The enclosure 100 has equilateral sides, i.e., it is essentially square.

The rear wall 106 includes a centrally-positioned access opening 124, standoffs 126A-D mounting screw keyholes 128A-D and mounting screw holes 130A-D. The mounting screw keyholes 128A-D stand proud of the rear surface of the base 102. Side wall 104D includes a base hinge element 132. Bosses 136A-H in the form of semispherical raised elements extend outwardly from the back surface of the rear wall 106 the same distance as the screw keyholes 128A-D. Insert plates 40 and 42, described above, are also usable with the enclosure 100. Access opening 124 is sized to receive the insert plates 40 and 42 side-by-side. In addition, insert plate 144 is sized to fit into the same opening 124, and locks into place with tabs 144A-D that includes semicircular openings that fit around the bosses 136A-D, respectively, to lock the insert plate 144 into place in the access opening 124. Support shoulders 144E and 144F extend between the tabs 144A, 144B and 144C, 144D to support the insert plate 46 in the access opening 124.

The base 102 also includes a base locking tab 148 positioned on a corner of the base 102 remote from the base hinge element 132 with a hole 150 formed therein.

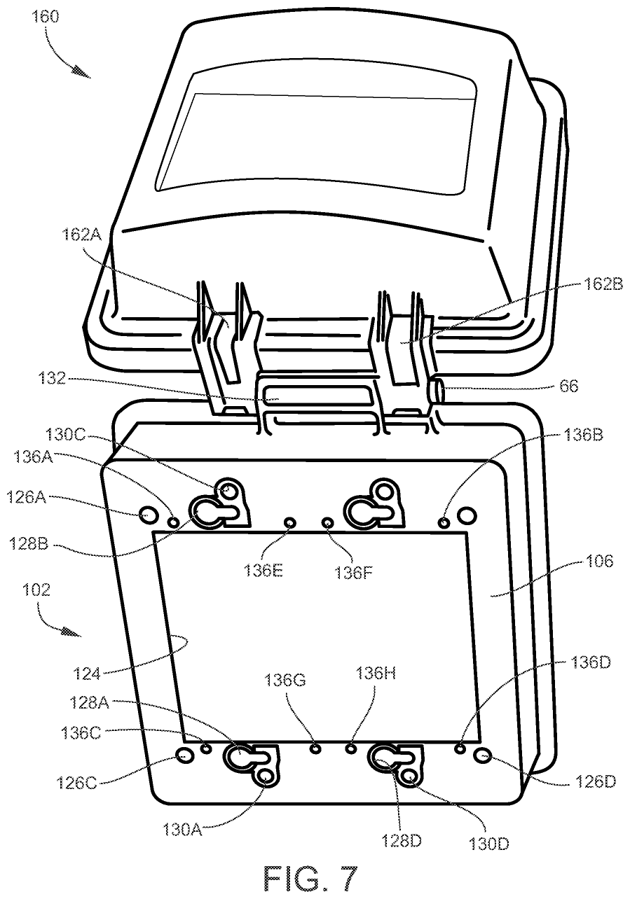

Referring to FIG. 7, a cover 160 is preferably fabricated of a transparent or semitransparent plastic and includes cover hinge elements 162A-B spaced-apart to receive base hinge element 132. The cover 160 is deep enough to fully close against the base 102. Cover hinge elements 162A-B are placed on either side of the base hinge element 132, and the hinge pin 66, see FIG. 1, is inserted in aligned openings, not shown, in the cover hinge elements 162A-B and 132.

The enclosure 100 can be mounted with the knockout panels 108A-C at the bottom with the cover 160 opening from the top, or mounted with the knockout panels 108A-C to one side in which case the cover 160 will open from the side.

The cover 160 includes a cover locking tab 168 formed on a corner of the cover 60 remote from cover hinge elements 162A-B. A hole 170 in the cover locking tab 168 aligns with the hole 150 in the base locking tab 148 when the cover 160 is closed and the cover 160 can be locked with a small padlock, zip-tie or some other means. A cover lift tab 172 formed on the corner of the cover 160 adjacent to the cover locking tab 168 provides a means of easily opening the cover 160 away from the base 102.

A electrical device enclosure according to the invention has been described with reference to specific embodiments and examples. Various details of the invention maybe changed without departing from the scope of the invention. Furthermore, the foregoing description of the preferred embodiments of the invention and best mode for practicing the invention are provided for the purpose of illustration only and not for the purpose of limitation, the invention being defined by the claims.

I claim:

1. An electrical device enclosure, comprising:
(a) a base having a base wall for being mounted to a supporting structure;
(b) at least one access opening in the base wall for receiving an insert plate having an electrical device opening for receiving an electrical device to extend therethrough;
(c) a plurality of raised bosses positioned on a rear side of the base wall proximate the access opening;
(d) the insert plate having thereon a plurality of attachment elements for cooperating with respective ones of the bosses for mounting the insert plate to the rear side of the base wall and against the supporting structure; and
(e) a raised cover pivotally-mounted on the base and movable for selectively enclosing and exposing the base.

2. An electrical device enclosure according to claim 1, and including a plurality of insert plates, each insert plate having at least one opening of a predetermined selected shape and size for receiving an electrical device of a predetermined selected shape and size to extend therethrough.

3. An electrical device enclosure according to claim 2, and including:
(a) at least one knockout panel formed on a wall edge of the base for being removed to receive an electrical cord therethrough;
(b) at least one base hinge member mounted on the base;
(c) at least one complementary cover hinge member mounted on the cover for cooperating with the base hinge member to receive a hinge pin.

4. An electrical device enclosure according to claim 3, wherein the access opening is sized to receive at least any two of the plurality of insert plates in a side-by-side relation.

5. An electrical device enclosure according to claim 3, and including a laterally outwardly-extending base tab formed on the base and a complimentary laterally outwardly-extending cover tab formed on the cover and positioned over the base tab when the cover is closed against the base, both the base tab and the cover tab having an opening therein in registration with each other to receive a lock.

6. An electrical device enclosure according to claim 5, wherein the base and the cover are rectangular and adapted to be positioned on the supporting structure with either a long side or a short side of the base and cover extending laterally in a side-to-side orientation.

7. An electrical device enclosure according to claim 6, and including:
(a) a first base hinge mounted on the long side of the base and a second base hinge mounted on the short side of the base;
(b) a first cover hinge mounted on the long side of the cover, a second cover hinge mounted on the short side of the cover and cooperating with a respective one of the first and second base hinge members to receive a hinge pin wherein the enclosure may be mounted on the supporting structure in an orientation permitting either the long side of the base or the short side of the base to be positioned laterally with respect to the supporting structure.

8. An electrical device enclosure, comprising:
(a) an equilateral base having a base wall for being mounted to a supporting structure;
(b) at least one access opening in the base wall for receiving at least two insert plates each having an electrical device opening for receiving an electrical device to extend therethrough;
(c) a plurality of raised bosses positioned on a rear side of the base wall proximate the access opening; and
(d) each of the at least two insert plates having thereon a plurality of attachment elements for cooperating with respective ones of the bosses for mounting the insert plate to the rear side of the base wall and against the supporting structure.

9. An electrical device enclosure according to claim 8, wherein the raised bosses are semispherical and the attachment elements comprise outwardly extending tabs having a semicircular opening sized to fit snugly around the raised semispherical bosses.

10. An electrical device enclosure according to claim 8, and including a plurality of insert plates, each insert plate having at least one opening of a predetermined selected shape and size for receiving an electrical device of a predetermined selected shape and size to extend therethrough.

11. An electrical device enclosure according to claim 8, and including at least one knockout panel formed on a wall edge of the base for being removed to receive an electrical cord therethrough.

12. An electrical device enclosure according to claim 8, and including at least one base hinge member mounted on the base and at least one complementary cover hinge member mounted on the cover for cooperating with the base hinge member to receive a hinge pin.

13. An electrical device enclosure kit, comprising:
(a) a first electrical device enclosure, comprising:
(I) a rectangular base having a base wall for being mounted to a supporting structure and adapted to be positioned on the supporting structure with either a long side or a short side of the base extending laterally in a side-to-side orientation.
(ii) at least one access opening in the base wall for receiving an insert plate having electrical device opening for receiving an electrical device to extend therethrough;
(iii) a plurality of raised bosses positioned on a rear side of the base wall proximate the access opening;
(iv) the insert plate having thereon a plurality of attachment elements for cooperating with respective ones of the bosses for mounting the insert plate to the rear side of the wall and against the supporting structure; and
(v) a raised cover pivotally-mounted on the base and movable for selectively enclosing and exposing the base;
(b) a second electrical device enclosure, comprising:
(I) an equilateral base having a base wall for being mounted to a supporting structure;
(ii) at least one access opening in the base wall for receiving at least two insert plates each having an electrical device opening for receiving an electrical device to extend therethrough;
(iii) a plurality of raised bosses positioned on a rear side of the base wall proximate the access opening; and
(iv) each of the at least two insert plates having thereon a plurality of attachment elements for cooperating with respective ones of the bosses for mounting the insert plate to the rear side of the wall and against the supporting structure; and
(c) each of the insert plates for both the rectangular and equilateral enclosure being sized to fit into the access opening of the rectangular base wall of the equilateral base and to be held in position by the raised bosses and attachment elements.

14. An electrical device enclosure kit according to claim 13, and including:
(a) at least one knockout panel formed on a wall edge of the base of both the rectangular and equilateral bases for being removed to receive an electrical cord therethrough;
(b) at least one base hinge member mounted on a wall edge of both the rectangular and equilateral bases; and
(c) at least one cover hinge mounted on a wall edge of both the rectangular and equilateral cover and cooperating with the base hinge members of respective rectangular and equilateral covers to receive a hinge pin.

15. An electrical device enclosure kit according to claim 13, wherein the access opening of the equilateral base wall is sized to receive at least any two of the plurality of insert plates in a side-by-side relation.

16. An electrical device enclosure kit according to claim 13, and including a laterally outwardly-extending base locking tab formed on each base and a complimentary laterally outwardly-extending cover locking tab formed on each cover and positioned over the base locking tab when the cover is closed against the base, both the base locking tab and the cover locking tab having an opening therein in alignment with each other to receive a lock.
